(19) United States
(12) Patent Application Publication
(10) Pub. No.: US 2007/0194970 A1
(43) Pub. Date: Aug. 23, 2007

(54) Device And Method For Encoding A Secondary Information Of A Secondary Channel Into A Channel Data Stream Of A Primary Channel

(75) Inventors: Willem Marie Julia Marcel Coene, Eindhoven (NL); Albert Hendrik Jan Immink, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTROINCS N.V., EINDHOVEN, NEHTERLANDS 5621 BA (NL)

(21) Appl. No.: 11/568,120

(22) PCT Filed: Apr. 19, 2005
(86) PCT No.: PCT/IB05/51270

§ 371 Date: Oct. 20, 2006

(30) Foreign Application Priority Data
Apr. 23, 2004 (EP) 04101703.9

(51) Int. Cl. H03M 1/12

(52) U.S. Cl. 341/155

(57) ABSTRACT

The present invention relates to a device in a corresponding method for encoding a secondary information (r) of a secondary channel into a channel data stream (3) of a primary channel, said channel data stream (3) comprising at least two symbol rows of channel symbols one-dimensionally evolving along a first direction (t) and aligned with each other along a second direction (r), said two directions constituting a two-dimensional lattice of symbol positions. To provide a device and a method for encoding which can be used in a two-dimensional storage system, it is proposed that the device comprises:—a primary encoder (11) for encoding a primary information (1) into said primary channel data stream (3) of said primary channel,—a secondary encoder (12) for encoding said secondary information (2) into a secondary channel data stream (6) for embedding into the recorded signal of said primary channel data stream (3) and—a parameter modulation means (13) for varying a recording parameter (7) for one or more symbol rows based on said secondary information around an average value (9) using a variation parameter (5), said recording parameter (7) being used for recording said primary channel data stream (3) on a record carrier (21), said variations being made such that said average value (9) remains substantially constant and that said modulations can be detected by a decoding device, said secondary information being encoded into said variations.

The present invention relates to a device and a corresponding method for encoding a secondary information of a secondary channel into a primary channel data stream of a primary channel, said primary channel data stream comprising at least two symbol rows of channel symbols one-dimensionally evolving along a first direction and aligned with each other along a second direction, said two directions constituting a two-dimensional lattice of symbol positions.

The invention relates further to a device and a corresponding method for decoding a secondary information of a secondary channel from a primary channel data stream of a primary channel. Still further, the present invention relates to a record carrier and a signal including a channel data stream. Finally, the present invention relates to a computer program for implementing said methods.

US 2002/0114460 A1 discloses a method of embedding a secondary signal of a secondary channel in the one-dimensional bit stream of a primary signal of a primary channel. For copy protection and digital rights management for recordable or rewritable data carriers it is required that a key can be written and rewritten in a hidden side channel, i.e. in the secondary channel. Therefore it is proposed in this document that the bit stream of the primary signal is distorted before outputting the bit stream of the primary signal such that the secondary signal is represented by a predetermined distortion. This document further discloses a method for detecting the secondary signal embedded in the one-dimensional bit stream of the primary signal, to corresponding apparatuses and to a corresponding data carrier.

Currently, optical and magnetic systems for data storage that use a multi-track read-out are developed. For instance, a new concept for two-dimensional optical storage where the information on a record carrier, such as an optical disc, fundamentally has a two-dimensional character is described in non-prepublished European Patent Application 02292937.6 (PHNL 021237). The aim is to realize an increase over the third generation of optical storage (Blu-ray Disc, BD, with a wavelength %=405 nm and a Numerical Aperture NA=0.85 with a factor of 2 in data density and a factor of 10 in data rate (for the same physical parameters of the optical read-out system). In this concept, the symbols (or bits) are organized in a broad spiral. Such a spiral consists of a number of symbol rows stacked upon each other with a fixed phase relation in the radial direction, so that the symbols are arranged on a 2D lattice. A 2D closed-packed hexagonal ordering of the symbols is preferred because it has a 15% higher packing fraction than the square lattice. Successive revolutions of the broad spiral are separated by a guard band consisting of one empty symbol row. For parallel read-out a multi-spot light-path can be used, where each spot has BD characteristics. The signal processing with equalization, timing recovery and symbol detection is carried out in a 2D way, that is, jointly over all the symbol rows within the broad spiral.

It is an object of the present invention to provide a device and a corresponding method for encoding a secondary information of a secondary channel into a channel data stream of a primary channel which can be used in such a two-dimensional storage system. Further, a corresponding device and method for decoding, a record carrier, a signal and a computer program for implementing said methods shall be provided.

The object is achieved according to the present invention by a device for encoding as claimed in claim 1.

A corresponding decoding device is defined in claim 8.

Corresponding methods are defined in claims 7 and 9. Furthermore, the present invention also relates to a record carrier as claimed in claim 10. Finally, the present invention relates to a computer program for implementing said methods as claimed in claim 11.

Suppose that the broad spiral consists of N symbol rows. Let p_{m,n} further denote a parameter (or property) that can be specified for each sample (with index m) of the signal waveform of each row (with index n). For this parameter p, its global average value can be considered within a certain window, that is, within a segment of the broad spiral with a length of, for instance, M samples:

$${\sum }_{n} {\sum }_{m} {p}_{m , n} = C$$

When C is non-zero, the parameter p can be transformed into the parameter q defined as:

$${q}_{m , n} = {p}_{m , n} - \frac{C}{MN}$$

such that the global average value of parameter q is indeed zero. The global average value is based on all rows of the broad spiral. The row-based average values of the parameter q can also be defined, with, for the n-th symbol row, the parameter δₙ given by:

$${δ}_{n} = {\sum }_{m} {q}_{m , n}$$

An obvious choice would be to have the same value for δₙ for all rows, that is: so that the global average is indeed zero, because all row-based averages are zero.
∀n:δₙ=0

The present invention is now based on the idea to consider temporary non-zero values of the row-based averages (δₙ≠0) over a predefined portion of the data stream for some but at least two rows such that the global average (averaged over the rows of the spiral within said predefined portion of the data stream) remains identical to zero:

$$< {δ}_{n} >= \frac{1}{N} {\sum }_{n} {δ}_{n} = 0$$

An obvious example—described for practical reasons, but not limiting the scope of the invention—is the following. Consider N=2L+1 rows in the spiral, numbered from 0 to 2L. Then L pairs of symbol rows can be considered, each i-th pair for instance consisting of the two symbol rows L−i and L+i as an example, where it is imposed that (apart from δ_{L}=0):
δ_{L+i}=−δ_{L-i}
so that the above equation for <δₙ> is satisfied. For an even number of symbol rows, a similar reasoning can be set-up so that all symbol rows can have non-zero row-averages. Suppose that segments of M samples (synchronous with the symbol clock) are used for the computation of the row-based averages. Per segment of M samples local deviations of the row-averages from zero can then be introduced. Per row-pair and per segment of M samples, for simplicity three possible outcomes with ternary signaling are assumed. The total capacity of such a side-channel (secondary channel) would thus amount to:

$$\frac{L}{M} {log}_{2} ( 3 )$$

According to the method disclosed in US 2002/0114460 A1, in case of a single symbol row as it is the case in the conventional single-track spiral format as used in CD, DVD and BD, there can only be offsets from the global average which is, of course, identical to the row-based average (there is only one row). In order to limit possible interference with control loops and servo, the length of the segments must be quite small: control loops like a phase-locked loop work by virtue of the fact that they steer the average parameter p (in this case, the phase error, or the equivalent parameter of it in a decision-directed maximum-likelihood timing recovery-scheme) to zero. For a multi-track system as proposed according to the present invention, the global average value remains zero so that there will be substantially no effect on control loops and servo.

The variation parameter, also called modulation depth, represents information about how much the recording parameter is varied. For example, the track pitch can be varied by +/−10%. In that case the variation parameter amounts to 0.1. This variation parameter is determined beforehand in such a way that the normal read out of the primary channel is not hampered. The average value is also preferably predetermined or determined during encoding, e.g. over a portion of the primary channel data stream.

Preferred embodiments of the invention are defined in the dependent claims. In an advantageous embodiment the secondary encoder is operative for encoding the secondary information into the channel data stream by making complementary variations of the recording parameter for pairs of two symbol rows. In this way it can be easily obtained that the average value of the global predetermined recording parameter remains substantially constant. In this way, preferably each pair of two symbol rows or, more precisely, the complementary variations of the recording parameter for such pairs of two symbol rows, is used for encoding one single bit of the secondary information.

Claims 3 to 5 define preferred embodiments where different recording parameters and variations thereof are used for encoding the secondary information into the channel data stream. Such variations can be employed by introducing local radial track shifts, by varying the pit-hole size (e.g. by varying the current during writing of information) and/or by introducing local offsets in the phase of one or more symbol rows, said local offsets in the phase being made with respect to the average value of the phase for all symbol rows. In all embodiments parameter variations can be tracked on a relative scale, i.e. the parameter from one or more symbol rows can be compared with parameters from other (reference) rows or with a reference that is formed by the average over all symbol rows.

For example, in timing recovery the secondary channel that is created by small phase variations, is not hampered by variations in disk speed or write channel frequency variations, because the reference itself is also available in the channel data stream and is recorded on a record carrier or transmitted in the whole signal, and is further read out simultaneously. Moreover, the timing recovery of the system or other loops that track certain parameters need not to be hampered by the variations that were put deliberately in the channel data stream, since they can track only average parameter variations over all the symbol rows.

Generally, the present invention can be used in any kind of two-dimensional storage system. Preferably, the channel symbols are located on the lattice points of a quasi-hexagonal, quasi-rectangular or quasi-square lattice and are arranged within a symbol area having a hexagonal, rectangular or square shape, respectively. Preferably, a two-dimensional closed-packed hexagonal ordering of the symbols is used because it has the highest packing fraction.

The invention will now be explained in more detail with reference to the drawings in which

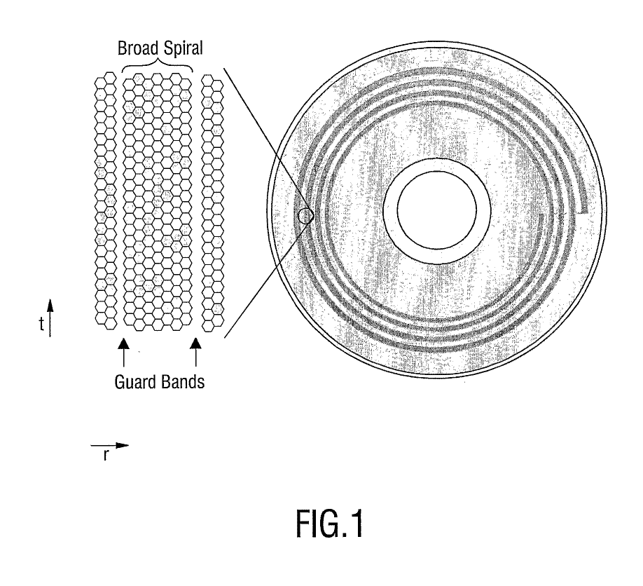

FIG. 1 shows the schematic format for two-dimensional optical storage,

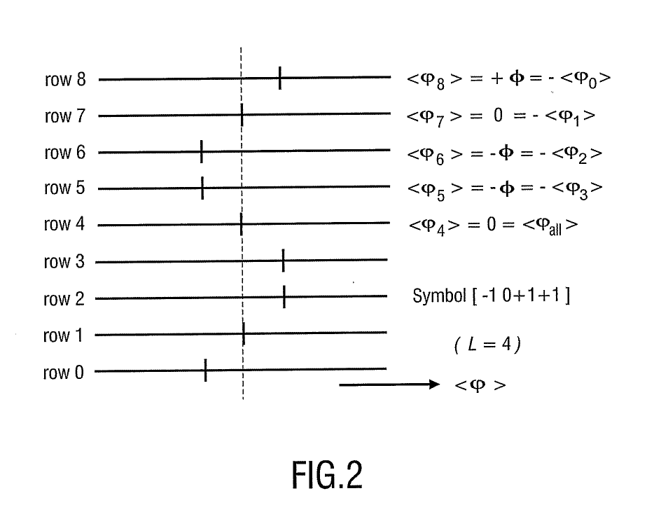

FIG. 2 illustrates the principle of using lattice distortions in the tangential direction of the broad spiral,

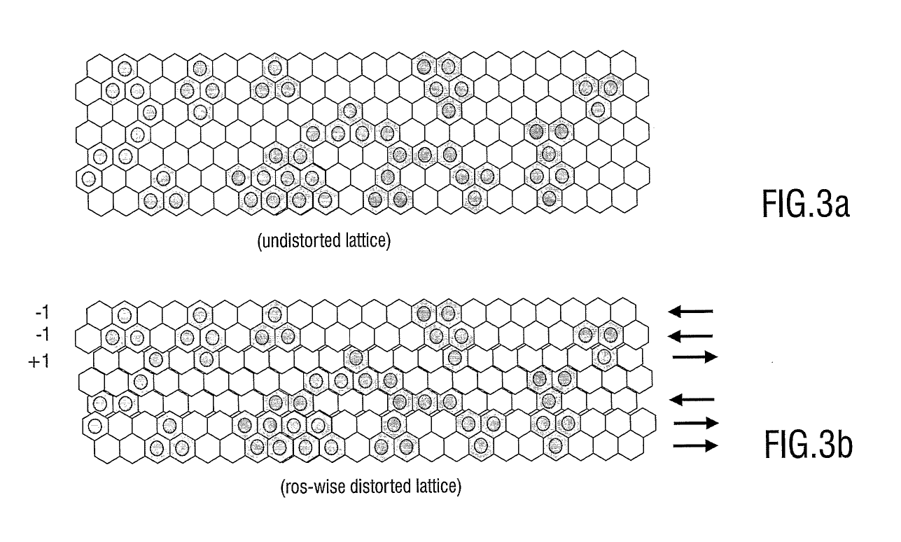

FIG. 3 shows part of an undistorted lattice and a distorted lattice to illustrate the principle of lattice distortions in the tangential direction,

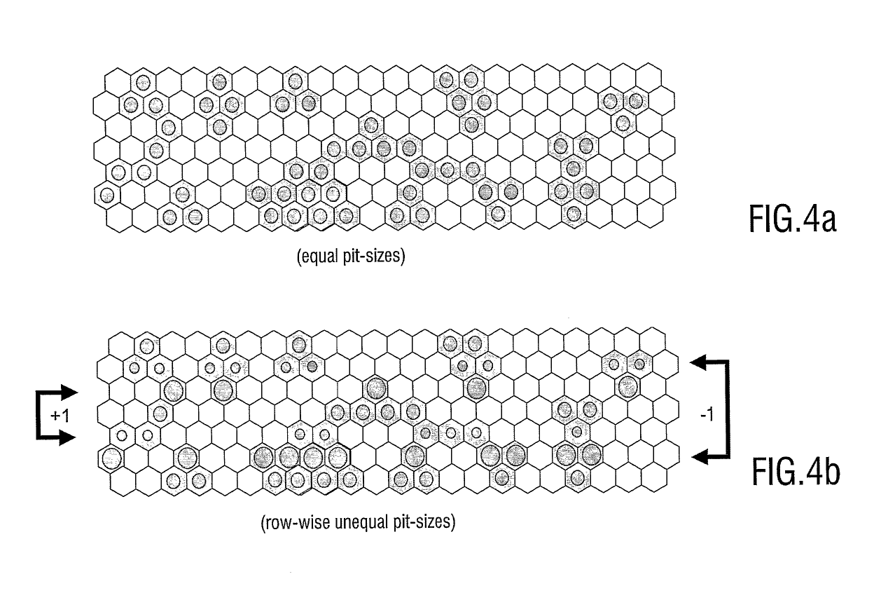

FIG. 4 shows several symbol rows to illustrate the principle of using radial track shifts,

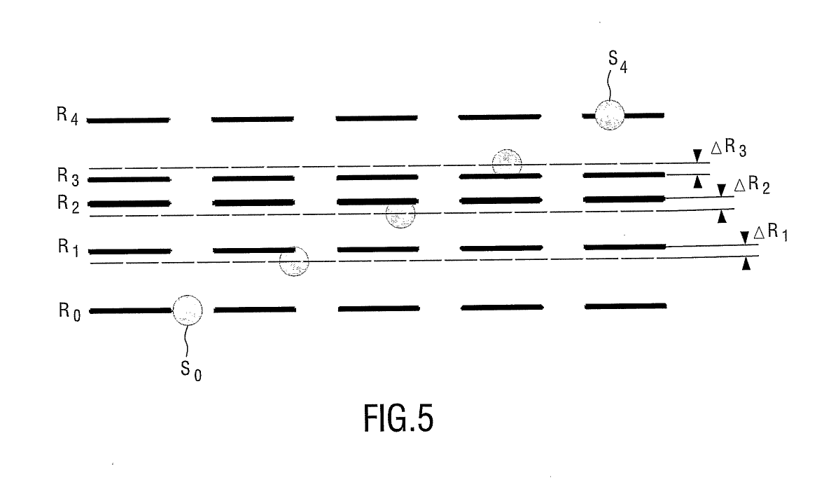

FIG. 5 shows parts of a broad spiral with either equal pit-sizes or row-wise unequal pit sizes to illustrate the principle of row-wise variations of the pit-sizes,

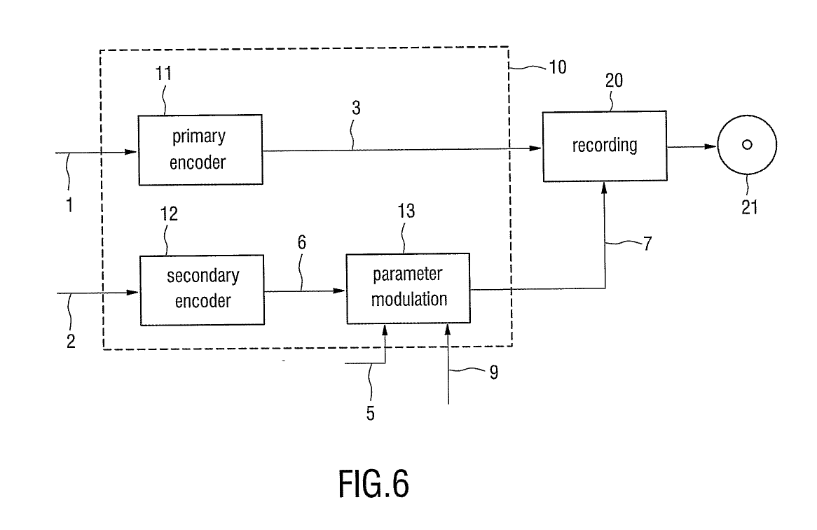

FIG. 6 shows a block diagram of an encoding apparatus according to the present invention and

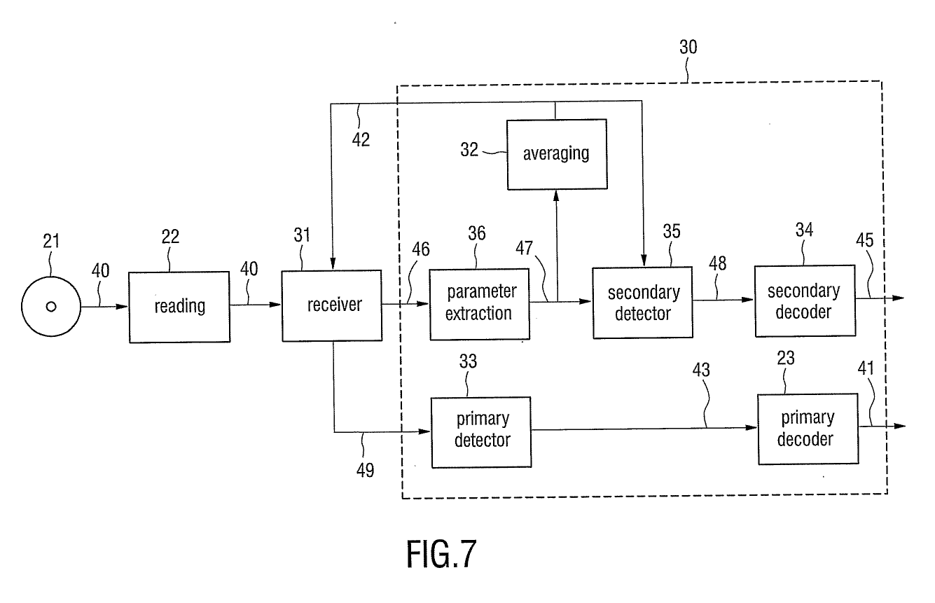

FIG. 7 shows a block diagram of a decoding apparatus according to the present invention.

In the following the special case of a broad spiral consisting of a number of symbol rows that are coherently stacked one upon the other, that is, each symbol row generally has a fixed phase relation (except for small variations that are subject of the present invention) with every other symbol row in the spiral, is considered. The schematic format for such a two-dimensional optical storage is shown in FIG. 1 (for simplicity a 7-row broad spiral is shown). Each hexagon corresponds with a symbol cell which can have, in this example two different bit values. Successive revolutions of the broad spiral are separated by a guard band. The channel symbols evolve along the tangential direction t, and the symbol rows are stacked upon each other in the radial direction r.

For such a system, a global timing recovery is to be implemented with a single timing parameter characterizing the tangential or lateral distance between symbols (along the direction of the spiral). This single parameter is the frequency of the digital timing oscillator (DTO) of the digital PLL. The parameter p to be identified in this case is the phase-error φ_{m,n} which is detected by the PLL for each row n relative to the zero-crossings of the single DTO. As a side-channel, information can be encoded in the local offset in the phase-error of each row (or more specifically, of each pair of symbol rows as applies for the practical example described above) compared to the global symbol clock of the spiral. In fact, in the write-channel this is implemented by delaying the bits in one row slightly compared to the global symbol clock: this is a kind of distortion of the 2D symbol lattice in the tangential direction. Its principle is shown schematically in FIG. 2 for the case of a 9-row broad spiral. In this example, row-pairs L+i and L−i have opposite phase-shifts defining one ternary symbol (0 when the phase-shift equals 0, −1 when the phase-shift of the top-row is negative, or +1 when the phase-shift of the top-row is positive). The phase-shift of each row is measured relative to the digital timing oscillator obtained for the overall broad spiral. The encoded symbol equals: [−1 0+1+1].

FIG. 3 shows a pictorial description with the row-shifts in the broad spiral. FIG. 3a shows an undistorted lattice; FIG. 3b shows a distorted lattice. The embodiment shown in FIG. 3b has equal but opposite phase-shifts for the symbol rows L+i and L−i, indicating symbols +1 or −1 depending on the sign of the phase-shift of for instance the top row L+i. If the phase-shifts are zero (not shown in FIG. 3), then the corresponding symbol equals 0. The phase-shift of each row is measured relative to the digital timing oscillator obtained for the overall broad spiral. With row “0” being the bottom symbol row in the spiral, the encoded symbol equals: [+1 +1 −1].

For some implementations of a PLL (based on zero-crossings), a complicating aspect might be that phase-errors are determined only at transitions in the symbol stream along a given symbol row, and that the number of transitions may vary from row to row; therefore, some fine-tuning of the lattice-distortion might be required in order to arrive at the global phase-error to be zero, meanwhile to have robust detection of the parameter-variation that is induced in a given row.

For decision-directed maximum-likelihood timing-recovery schemes, the equivalent parameter of the phase-error is obtained at each symbol sample. Other control loops like for a row-based adaptive equalizer, should not interfere with the induced row-based lattice-distortions. This might be difficult to achieve in practice, because the adaptive equalizer must still be able to introduce some asymmetry in its tap-coefficients for instance to compensate for asymmetries in the physical read-out due to tilt (of the laser beam with respect to the record carrier): one way to circumvent this problem, is to consider one global adaptive equalizer designed to operate on all the symbol rows (and thus having a characteristic that is row-independent). Further, spread-spectrum techniques may be used to achieve reliable detection even in the case of very small signals in the physical side-channel.

In a further embodiment of the invention not affecting the radial servo or the focus servo are proposed. Local radial track shift with small offsets can be introduced such that the radial servo and focus servo are not influenced. This can be considered as a kind of local lattice distortion in the radial direction. It has to be used in conjunction with a servo for the orientation of the diffraction grating that is producing the array of spots used for the parallel read-out of the broad spiral. Such a grating-servo can be based on the radial position of the outer symbol rows (if radial tracking is done with the artificial push-pull method that uses the average difference in amplitude of the central aperture signals of the outer rows as adopted in the two-dimensional optical storage system); two inner symbol rows can then have a radial offset, not affecting the overall control parameter, but the individual offsets can be measured from the individual signals.

FIG. 4 shows five symbol rows where the outer two spots S₀ and S₄ are exactly on track due to the artificial push-pull method. The inner rows R1, R2, R3 can have small, local track offsets AR that can be used to implement the secondary channel.

In another embodiment of the invention variations in pit-size are proposed. In two-dimensional optical storage, each pit-bit is mastered as a (circular) pit-hole covering around 50% of the hexagonal bit-cell. In a certain local area of the broad spiral pits can be mastered in different rows with different sizes, which will affect the DC level of the signal waveform of each of the rows. Supposing a common DC-control for all the symbol rows in the spiral, by changing the pit-hole size in a symbol row, the DC-level will change. The idea is now to change the pit-hole sizes in a certain area of the broad spiral for at least two symbol rows, such that the overall control parameter for all the symbol rows together will not be influenced, for instance by making the pit-hole size in one row slightly larger, and for the other row slightly smaller, for the case of two symbol rows. The control signals for the individual rows where the pit-hole size has been changed will indicate offsets from the average control parameter, thus allowing detection of the side information (secondary information).

The principle of the change in pit-hole sizes with an implementation having one ternary symbol for each pair of symbol rows L+i and L−i is shown in FIG. 5. FIG. 5a shows part of a broad spiral with all-equal pit-sizes; FIG. 5b shows part of a broad spiral with unequal pit-sizes, with row-pairs L+i and L−i having smaller/larger or larger/smaller pit-sizes compared to the nominal case, or having equal pit-sizes compared to the nominal case, defining the respective symbol +1, −1 and 0. With row “0” being the bottom symbol row in the spiral, the encoded symbol equals: [0 +1 −1].

FIG. 6 schematically shows an encoding apparatus 10 according to the present invention as a block diagram. The encoding apparatus 10 comprises a primary encoder 11 for encoding a primary information 1 of a primary channel into a channel data stream 3. For encoding a secondary information 2 a secondary encoder 12 is provided by which said secondary information 2 shall be encoded to a secondary channel data stream 6 which is embedded into the recorded signal of the primary channel data stream, i.e. the signal the is finally recorded on the record carrier 21, by varying a recording parameter during the recording of the primary channel data stream 3. Therefore, the secondary channel data stream 6 is input to a parameter modulation unit 13 which introduces variations in at least one of the recording parameters 7 based on a further parameter 5, which is called variation parameter or modulation depth. These variations deviate from a nominal (average) value 9 for each symbol row. Such variations can be, as explained above, the introduction of local radial track shifts, the variation of the pit-hole sizes or the introduction of local offsets in the phase. Such variations are made in such a way that the average value substantially remains constant, so that the primary information can be read out and decoded from the final channel data stream without any particular measures.

The variation parameter 5 is preferably predetermined and given. It includes information of how much the (also predetermined or determined during encoding, e.g. by use of a—not shown—averaging unit) average value of the recording parameters shall be varied to encode the secondary information 2.

The recording unit 20 then records the primary channel data stream 3 onto a record carrier 21 using the recording parameters 7 in this way embedding the secondary information in the primary channel data stream 3. The record carrier 21 can for instance be an optical disc.

FIG. 7 schematically shows a decoding apparatus 30 according to the present invention as a block diagram. After reading the replay signal 40 from a record carrier 21 by a reading unit 22, the replay signal 40 is provided to a receiver unit 31. The receiver unit processes the replay signal to a bit-synchronous sample stream 49 that is input to a primary detector 33. The output of the primary detector 33 is provided to a primary decoder 23 where already the primary information 41 of the primary channel can be decoded.

The receiver 31 furthermore provides information 46 to a parameter extraction unit 36 from which said parameter extraction unit 36 extracts the recording parameters of interest 47 for each of the rows. In the decoding apparatus the global recording parameter of a portion of said channel data stream is obtained by an averaging unit 32. Said average value 42 as well as the extracted recording parameters 47 are then provided to a secondary detection unit 35. Therein variations of the value of the recording parameters are detected compared to said average value 42 for one or more symbol rows. Said detected variations 48 are then provided to a secondary decoder 34 which decodes the secondary information 45 from such variations.

It should be noted that each variation of a given parameter gives a very small performance loss. Therefore, the variations (determined by the variation parameter, i.e. the modulation depth) should be kept as small as possible, and averaging over relatively long data-blocks should lead to reasonably accurate detection of this type of side information. In this context, spread-spectrum modulation techniques might be of interest to achieve very robust detection of very small amplitude signals.

With a system with multi-track read-out (as for the two-dimensional optical format with a broad spiral consisting of a number of symbol rows), a parameter can be defined that has a global value for the complete broad spiral, that is, averaged for all the symbol rows within the spiral. In local sections of the broad spiral, row-wise variations (or deviations) of the same parameter relative to the global value of that parameter can be introduced, hereby constituting a side-channel with side-information that can be used for copy-protection. The row-wise variations are chosen such that the global value of the parameter remains identical whether or not the row-wise variations are present.

Although the invention has been elucidated with reference to the embodiments described above, it will be evident that other embodiments may be alternatively used to achieve the same object. The scope of the invention is therefore not limited to the embodiments described above.

It should further be noted that use of the verb “comprises/comprising” and its conjugations in this specification, including the claims, is understood to specify the presence of stated features, integers, steps or components, but does not exclude the presence or addition of one or more other features, integers, steps, components or groups thereof. It should also be noted that the indefinite article “a” or “an” preceding an element in a claim does not exclude the presence of a plurality of such elements. Moreover, any reference sign does not limit the scope of the claims; the invention can be implemented by means of both hardware and software, and several “means” may be represented by the same item of hardware. Furthermore, the invention resides in each and every novel feature or combination of features.

1. Device for encoding a secondary information (2) of a secondary channel into a primary channel data stream (3) of a primary channel, said primary channel data stream (3) comprising at least two symbol rows of channel symbols one-dimensionally evolving along a first direction (t) and aligned with each other along a second direction (r), said two directions constituting a two-dimensional lattice of symbol positions, comprising:
a primary encoder (11) for encoding a primary information (1) into said primary channel data stream (3) of said primary channel,
a secondary encoder (12) for encoding said secondary information (2) into a secondary channel data stream (6) for embedding into the recorded signal of said primary channel data stream (3) and
a parameter modulation means (13) for varying a recording parameter (7) for one or more symbol rows based on said secondary information around an average value (9) using a variation parameter (5), said recording parameter (7) being used for recording said primary channel data stream (3) on a record carrier (21), said variations being made such that said average value (9) remains substantially constant and that said modulations can be detected by a decoding device, said secondary information being encoded into said variations.

2. Device as claimed in claim 1, wherein said secondary encoder (12) is operative for encoding said secondary information (2) into said primary channel data stream (3) by making complementary variations of said recording parameter for pairs of two symbol rows.

3. Device as claimed in claim 1, wherein said secondary encoder (12) is operative for introducing local radial track shifts for one or more symbol rows.

4. Device as claimed in claim 1, wherein said secondary encoder (12) is operative for varying the pit-hole size for one or more symbol rows.

5. Device as claimed in claim 1, wherein said secondary encoder (12) is operative for introducing local offsets in the phase of one or more symbol rows with respect to the average value of the phase for all symbol rows.

6. Device as claimed in claim 1, wherein said channel symbols are located on the lattice points of a quasi-hexagonal, quasi-rectangular or quasi-square lattice and are arranged within a symbol area having a hexagonal, rectangular or square shape, respectively.

7. Method for encoding a secondary information (2) of a secondary channel into a primary channel data stream (3) of a primary channel, said primary channel data stream (3) comprising at least two symbol rows of channel symbols one-dimensionally evolving along a first direction (t) and aligned with each other along a second direction (r), said two directions constituting a two-dimensional lattice of symbol positions, comprising the steps of:
encoding a primary information into said primary channel data stream (3) of said primary channel,
encoding said secondary information (2) into a secondary channel data stream (6) for embedding into the recorded signal of said primary channel data stream (3) and
varying a recording parameter (7) for one or more symbol rows based on said secondary information around an average value (9) using a variation parameter (5), said recording parameter (7) being used for recording said primary channel data stream (3) on a record carrier (21), said variations being made such that said average value remains substantially constant and that such variations can be detected by a decoding device, said secondary information being encoded into said variations.

8. Device for decoding a secondary information (45) of a secondary channel from a received replay signal (40) of a primary channel data stream (43) of a primary channel, said primary channel data stream (43) comprising at least two symbol rows of channel symbols one-dimensionally evolving along a first direction (t) and aligned with each other along a second direction (r), said two directions constituting a two-dimensional lattice of symbol positions, comprising:
a parameter extraction means (36) for extracting a parameter information about the recording parameter which has been varied for encoding said secondary information into said primary channel data stream (43) from said received replay signal (40),
an averaging means (32) for determining an average value of a global recording parameter of a portion of said replay signal (40), said recording parameter being identified by said parameter information,
a detection means (35) for detecting the secondary channel information (48) from the variations of said extracted recording parameter (47) compared to said average value (42) for one or more symbol rows, and
a secondary decoder (34) for decoding said secondary information from detected variations of said recording parameter.

9. Method for decoding a secondary information (45) of a secondary channel from a replay signal (40) of a primary channel data stream (43) of a primary channel, said primary channel data stream (43) comprising at least two symbol rows of channel symbols one-dimensionally evolving along a first direction (t) and aligned with each other along a second direction (r), said two directions constituting a two-dimensional lattice of symbol positions, comprising the steps of:
extracting a parameter information about the recording parameter which has been varied for encoding said secondary information into said primary channel data stream (43) from said received replay signal (40),
determining an average value of a global recording parameter of a portion of said replay signal (40), said recording parameter being identified by said parameter information,
detecting the secondary channel information (48) from the variations of said extracted recording parameter (47) compared to said average value (42) for one or more symbol rows, and
decoding said secondary information from detected variations of said recording parameter.

10. Record carrier (21) having recorded thereon a primary channel data stream (43) carrying a primary information (1) of a primary channel into which a secondary information (2) of a secondary channel is encoded, said primary channel data stream (43) comprising at least two symbol rows of channel symbols one-dimensionally evolving along a first direction (t) and aligned with each other along a second direction (r), said two directions constituting a two-dimensional lattice of symbol positions, wherein one or more symbol rows have been recorded using a recording parameter (7) which has been varied based on said secondary information (2) around an average value (9) using a variation parameter (5) such that said average value (9) remains constant over a portion of said primary channel data stream, said variations being detectable by a decoding device.

11. Computer program comprising program code means for causing a computer to carry out the methods as claimed in claim 7 when said computer program is executed on a computer.
